(19) United States
(12) Patent Application Publication
(10) Pub. No.: US 2024/0333254 A1
(43) Pub. Date: Oct. 3, 2024

(54) SINGLE CRYSTALLINE FILM BULK ACOUSTIC RESONATOR AND RELATED SYSTEMS AND METHODS

(71) Applicant: Massachusetts Institute of Technology, Cambridge, MA (US)

(72) Inventors: Sang-Gook Kim, Wayland, MA (US); Jeehwan Kim, Cambridge, MA (US)

(73) Assignee: Massachusetts Institute of Technology, Cambridge, MA (US)

(21) Appl. No.: 18/580,593

(22) PCT Filed: Jul. 19, 2022
(86) PCT No.: PCT/US2022/037537

§ 371 Date: Jan. 18, 2024

Related U.S. Application Data
(60) Provisional application No. 63/223,205, filed on Jul. 19, 2021.

(51) Int. Cl. H03H 9/17; H03H 3/02

(52) U.S. Cl. CPC H03H 9/173; H03H 3/02

(57) ABSTRACT

Resonators comprising a single-crystalline semiconductor, and related systems and methods, are generally described.

### RELATED APPLICATIONS

This application claims priority under 35 U.S.C. § 119 (e) to U.S. Provisional Patent Application No. 63/223,205, filed Jul. 19, 2021, and entitled “Single Crystalline Film Bulk Acoustic Resonator and Related Systems and Methods,” which is incorporated herein by reference in its entirety for all purposes.

### TECHNICAL FIELD

Resonators comprising a single-crystalline semiconductor, and related systems and methods, are generally described.

### BACKGROUND

Film bulk acoustic resonators (FBARs) containing piezoelectric materials are utilized as radio frequency (RF) filters for wireless devices (e.g., cell phones) and related applications. FBARs are designed to remove unwanted frequencies from being transmitted in such devices, while allowing other specific frequencies to be received and transmitted. FBAR's have partially replaced an earlier technology based on surface acoustic wave (SAW) devices, due to smaller size and increased fabrication and operating efficiencies.

### SUMMARY

Resonators comprising a single-crystalline semiconductor, and related systems and methods, are generally described. The subject matter of the present invention involves, in some cases, interrelated products, alternative solutions to a particular problem, and/or a plurality of different uses of one or more systems and/or articles.

According to certain embodiments, a device is described, the device comprising a substrate comprising a cavity, a single-crystalline semiconductor material positioned at least partially over the cavity of the substrate, a first contact, and a second contact. In some embodiments, the first contact is between the substrate and the single-crystalline semiconductor material, and the first contact and the single-crystalline semiconductor material form a first Ohmic contact. In certain embodiments, the single-crystalline semiconductor material is between the first contact and the second contact, and the second contact and the single-crystalline semiconductor material form a second Ohmic contact.

According to some embodiments, a method of forming a device is described, the method comprising transferring a single-crystalline semiconductor material and a first contact from a first substrate to a second substrate such that at least a portion of the single-crystalline semiconductor material is positioned over a cavity of the second substrate, and forming a second contact over a side of the single-crystalline semiconductor material that is opposite a side of the single-crystalline semiconductor material that is facing the second substrate. In certain embodiments, after the transferring and the forming, the first contact is between the second substrate and the single-crystalline semiconductor material, and the first contact and the single-crystalline semiconductor material form a first Ohmic contact. In some embodiments, after the transferring and the forming, the single-crystalline semiconductor material is between the first contact and the second contact, and the second contact and the single-crystalline semiconductor material form a second Ohmic contact.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIG. 1A shows, according to certain embodiments, a cross-sectional schematic diagram of a device;

FIG. 1B shows, according to certain embodiments, a top-view schematic diagram of a device; and

FIG. 2 shows, according to certain embodiments, a method of forming a device.

### DETAILED DESCRIPTION

Resonators comprising a single-crystalline semiconductor, and related systems and methods, are generally described.

The inventors have recognized that there is an unmet need and opportunity for innovation in the field of resonators (e.g., for use in wireless devices). Conventional film bulk acoustic resonators are fabricated by depositing a piezoelectric material directly on an electrical contact disposed on a substrate wafer. The fabrication process results in a polycrystalline piezoelectric material due to the high lattice mismatch between the electrical contact and the piezoelectric material being deposited. Furthermore, the deposition of the piezoelectric material is followed by an inefficient etching process through the back of the substrate wafer to access the piezoelectric material. Such polycrystalline materials are unsuitable for advancing wireless applications, such as fifth generation (5G) mobile networks, due to low piezoelectric coefficients and/or low figures of merit resulting from the polycrystalline material. In addition, conventional efforts of fabricating single-crystalline semiconductor materials, such as epitaxial growth of semiconducting materials on sapphire followed by laser lift-off techniques, result in materials that are too thick for use as film bulk acoustic resonators.

Described herein is a device comprising a single-crystalline semiconductor material. The device may be, in some embodiments, a resonator, such as a film bulk acoustic resonator. The single-crystalline semiconductor material is grown (e.g., epitaxially grown), in certain embodiments, over a two-dimensional (2D) material positioned over a source (e.g., growth) substrate that is lattice-matched with the single-crystalline semiconductor material. In some such embodiments, a potential field from the growth substrate reaches beyond the 2D material such that the growth substrate seeds the growth of the single-crystalline film, even in cases where the 2D material is continuous. That is to say, the growth substrate can, in some embodiments, seed the growth of the single-crystalline material even when the 2D material is not patterned or otherwise arranged to have through thickness defects that allow for direct contact between the growth substrate and the single-crystalline film. In some embodiments, the potential field from the growth substrate penetrates through the 2D material to facilitate growth of the single-crystalline semiconductor with substantially no defects. In certain embodiments, the single-crystalline semiconductor material may then be transferred from the growth substrate to a preconfigured performance substrate, thereby bypassing the need to back-etch the performance substrate to reach the semiconductor material.

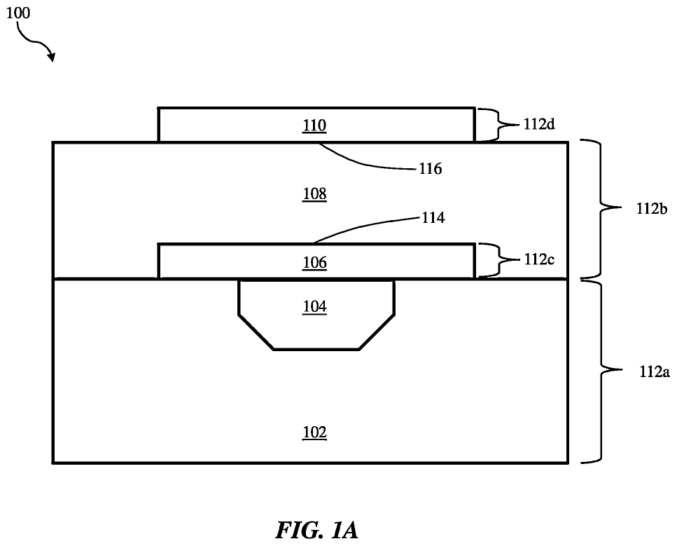

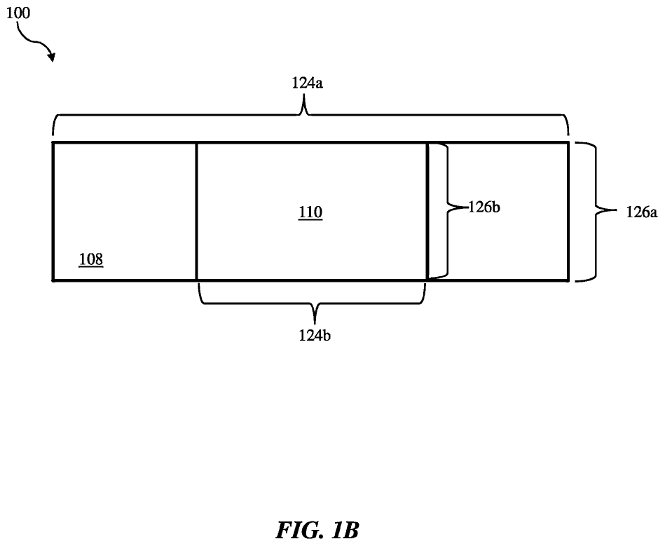

In some embodiments, the device comprises a substrate comprising a cavity. FIG. 1A shows, according to certain embodiments, a cross-sectional schematic diagram of a device. As shown in FIG. 1A, device 100 comprises substrate 102 comprising cavity 104. In some embodiments, and as shown in FIG. 1A, the cavity may extend only partially through the bulk of the substrate.

The cavity may be any of a variety of suitable shapes and/or sizes. According to certain embodiments, for example, the cavity may be square shaped and/or circular shaped. Other shapes are also possible.

The substrate may comprise any of a variety of suitable materials. In certain embodiments, for example, the substrate comprises silicon (Si) and/or silicon dioxide (SiO₂) (e.g., quartz, window glass). The cavity can be occupied by any of a variety of non-solid materials (such as any of a variety of gases), in accordance with certain embodiments.

The substrate may have any of a variety of suitable thicknesses. Referring to FIG. 1A, for example, substrate 102 has thickness 112a, in accordance with certain embodiments. In some embodiments, the substrate has a thickness of less than or equal to 5 centimeters, less than or equal to 1 centimeter, less than or equal to 5 millimeters, less than or equal to 1 millimeter, less than or equal to 500 micrometers, less than or equal to 200 micrometers, less than or equal to 100 micrometers, less than or equal to 50 micrometers, less than or equal to 30 micrometers, less than or equal to 25 micrometers, less than or equal to 20 micrometers, less than or equal to 15 micrometers, less than or equal to 10 micrometers, less than or equal to 5 micrometers, or less. In certain embodiments, the substrate has a thickness of greater than or equal to 1 micrometer, greater than or equal to 5 micrometers, greater than or equal to 10 micrometers, greater than or equal to 15 micrometers, greater than or equal to 20 micrometers, greater than or equal to 25 micrometers, greater than or equal to 50 micrometers, greater than or equal to 100 micrometers, greater than or equal to 200 micrometers, greater than or equal to 500 micrometers, or more. Combinations of the above recited ranges are possible (e.g., the substrate has a thickness of greater than or equal to 1 micrometer and less than or equal to 1 centimeter, greater than or equal to 1 micrometer and less than or equal to 1 millimeter, or greater than or equal to 10 micrometers and less than or equal to 20 micrometers). Other ranges are also possible.

According to certain embodiments, the device comprises a single-crystalline semiconductor material. Referring, for example, to FIG. 1A, device 100 comprises single-crystalline semiconductor material 108. According to certain embodiments, single-crystalline semiconductor material 108 may be positioned at least partially over cavity 104 of substrate 106. Advantageously, configuring the device this way acoustically isolates the single-crystalline semiconductor material, while also not providing access to the single-crystalline semiconductor material from the backside of the device.

In some embodiments, the single-crystalline semiconductor material is a piezoelectric material. As used herein, the term “piezoelectric material” is given its ordinary meaning in the art and generally refers to material that has the ability to generate internal electrical charge from applied mechanical stress. In some embodiments, the piezoelectric material comprises a semiconductor material. In certain embodiments, the piezoelectric material comprises an insulator material.

In certain embodiments, the single-crystalline semiconductor material comprises a III-nitride material. The term “III-nitride material” is used herein to refer to any Group III element-nitride compound. Non-limiting examples of III-nitride materials include boron nitride (BN), aluminum nitride (AlN), gallium nitride (GaN), indium nitride (InN), and thallium nitride (TIN), as well as any alloys including Group III elements and Group V elements (e.g., AlxGa₍₁₋ₓ₎N, AlxInyGa_{(1-x-y)}N, InxGa₍₁₋ₓ₎N, AlxIn₍₁₋ₓ₎N, GaAsaPbN_{(1-a-b)}, AlxInyGa_{(1-x-y)}ASaPbN_{(1-a-b)}, and the like). III-nitride materials may be doped n-type or p-type, or may be intrinsic.

The phrase “aluminum nitride material” refers to aluminum nitride (AlN) and any of its alloys, such as aluminum gallium nitride (AlxGa₍₁₋ₓ₎N), aluminum indium nitride (AlxIn₍₁₋ₓ₎N), aluminum indium gallium nitride (AlxInyGa_{(1-x-y)}N), aluminum indium gallium arsenide phosphoride nitride (AlxInyGa_{(1-x-y)}ASaPbN_{(1-a-b)}), and the like. In certain embodiments, the aluminum nitride material comprises AlN.

The phrase “gallium nitride material” refers to gallium nitride (GaN) and any of its alloys, such as aluminum gallium nitride (AlxGa₍₁₋ₓ₎N), indium gallium nitride (In_{y}Ga_{(1-y)}N), aluminum indium gallium nitride (AlxInyGa_{(1-x-y)}N), gallium arsenide phosphoride nitride (GaAsₐP_{b}N_{(1-a-b)}), aluminum indium gallium arsenide phosphoride nitride (AlₓIn_{y}Ga_{(1-x-y)}ASₐP_{b}N_{(1-a-b)}), and the like. In certain embodiments, the gallium nitride material comprises GaN.

According to certain embodiments, the single-crystalline material comprises a III-phosphide material. The term “III-phosphide material” is used herein to refer to any Group III element-phosphide compound. Non-limiting examples of III-phosphide materials include gallium phosphide (GaP), boron phosphide (BP), aluminum phosphide (AlP), indium phosphide (InP), and thallium phosphide (TIP), as well as any alloys including Group III elements and Group V elements (e.g., AlxGa₍₁₋ₓ₎P, AlxInyGa_{(1-x-y)}P. InxGa₍₁₋ₓ₎P, AlxIn₍₁₋ₓ₎P, GaAsₐP_{b}N_{(1-a-b)}, AlₓIn_{y}Ga_{(1-x-y)}ASₐP_{b}N_{(1-a-b)}, and the like). III-phosphide materials may be doped n-type or p-type, or may be intrinsic.

In some embodiments, the single-crystalline material comprises a III-arsenide material. The term “III-arsenide material” is used herein to refer to any Group III element-arsenide compound. Non-limiting examples of III-arsenide materials include gallium arsenide (GaAs), boron arsenide (BAs), aluminum arsenide (AlAs), indium arsenide (InAs), and thallium arsenide (TlAs), as well as any alloys including Group III elements and Group V elements (e.g., AlxGa₍₁₋ₓ₎As, AlxInyGa_{(1-x-y)}As, InxGa₍₁₋ₓ₎As, AlₓIn₍₁₋ₓ₎P, GaAsₐAs_{b}N_{(1-a-b)}, AlₓIn_{y}Ga_{(1-x-y)}ASₐP_{b}N_{(1-a-b)}, and the like). III-arsenide materials may be doped n-type or p-type, or may be intrinsic.

In some embodiments, the single-crystalline semiconductor material comprises an oxide (e.g., a metal oxide). The metal oxide may be, in certain embodiments, zinc oxide (ZnO). Other oxides are also possible, according to some embodiments, such as barium titanate (BaTiO₃ or BTO), barium strontium titanate (BaₓSr₁₋ₓTiO₃ or BST), strontium titanate (SrTiO₃ or STO), strontium ruthenium oxide (SrRuO₃ or SRO), lanthanum aluminate (LaAlO₃ or LAO), lead magnesium niobate-lead titanate (Pb(Mg_{1/3}Nb_{2/3})O₃—PbTiO₃ or PMN-PT), yttrium iron garnet (Y₃Fe₅O₁₂ or YIG), lithium niobate (LiNbO₃), lithium titanate (LizTiO₃), and the like. In some embodiments, the single-crystalline semiconductor material comprises a perovskite.

The single-crystalline semiconductor material may have any of a variety of suitable thicknesses. Referring to FIG. 1A, for example, single-crystalline semiconductor material 108 has thickness 112b. Without wishing to be bound by theory, in some embodiments, the single-crystalline semiconductor material may have a thickness that is suitable for film bulk acoustic resonators used for fifth generation (5G) mobile networks.

In certain embodiments, the single-crystalline semiconductor material has a thickness less than or equal to 10 micrometers, less than or equal to 5 micrometers, less than or equal to 2 micrometers, less than or equal to 1 micrometer, less than or equal to 500 nm, less than or equal to 200 nm, less than or equal to 100 nm, or less than or equal to 50 nm. In some embodiments, the single-crystalline semiconductor material has a thickness greater than or equal to 20 nm, greater than or equal to 50 nm, greater than or equal to 100 nm, greater than or equal to 200 nm, greater than or equal to 500 nm, greater than or equal to 1 micrometer, greater than or equal to 2 micrometers, or greater than or equal to 5 micrometers. Combinations of the above recited ranges are also possible (e.g., the single-crystalline semiconductor material has a thickness of less than or equal to 10 micrometers and greater than or equal to 20 nm, the single-crystalline semiconductor material has thickness less than or equal to 1 micrometer and greater than or equal to 200 nm). Other ranges are possible.

The single-crystalline semiconductor material may have any of a variety of suitable lengths and/or widths. FIG. 1B shows, according to certain embodiments, a top-view schematic diagram of a device. As shown in FIG. 1B, single-crystalline semiconductor material has length 124a and width 126a, in accordance with some embodiments. In some embodiments, the single-crystalline material has a length and/or width of greater than or equal to 1 micrometer, greater than or equal to 10 micrometers, greater than or equal to 100 micrometers, greater than or equal to 300 micrometers, greater than or equal to 500 micrometers, greater than or equal to 1 mm, greater than or equal to 10 mm, or greater. In certain embodiments, the single-crystalline material has a length and/or width of less than or equal to 100 mm, less than or equal to 10 mm, less than or equal to 1 mm, less than or equal to 500 micrometers, less than or equal to 300 micrometers, less than or equal to 100 micrometers, less than or equal to 10 micrometers, or less. Combinations of the above recited ranges are possible (e.g., the single-crystalline material has a length and/or width of greater than or equal to 1 micrometer and less than or equal to 100 mm, or greater than or equal to 300 micrometers and less than or equal to 1 mm). Other ranges are also possible.

The single-crystalline material may have any of a variety of suitable facial surface areas. The term “facial surface area” is used to describe the surface area of a major surface of the layer (which, generally, is the same for each major surface of the layer). In some embodiments, the single-crystalline material has a major surface having a facial surface area of greater than or equal to 1 μm², greater than or equal to 10 μm², greater than or equal to 100 μm², greater than or equal to 1 mm², greater than or equal to 10 mm², greater than or equal to 100 mm², greater than or equal to 1,000 mm², or greater. In certain embodiments, the single-crystalline material has a major surface having a facial surface area of less than or equal to 10,000 mm², less than or equal to 1,000 mm², less than or equal to 100 mm², less than or equal to 10 mm², less than or equal to 1 mm², less than or equal to 100 μm², less than or equal to 10 μm², or less. Combinations of the above recited ranges are possible (e.g., the single-crystalline material has a major surface having a facial surface area of greater than or equal to 1 μm² and less than or equal to 10,000 mm², or greater than or equal to 1 mm² and less than or equal to 10 mm²). Other ranges are also possible.

According to certain embodiments, although not shown in the figures, one or more intermediate layers may be positioned between the substrate and the single-crystalline semiconductor material. In some such embodiments, the one or more intermediate layers may be configured as described above with respect to the substrate.

According to certain embodiments, the device comprises a first contact. Referring to FIG. 1A, for example, device 100 comprises first contact 106. In some embodiments, first contact 106 is between substrate 102 and single-crystalline semiconductor material 108.

In certain embodiments, the device comprises a second contact. Referring again to FIG. 1A, for example, device 100 comprises second contact 110.

“Contact,” in the context of first contact 106 and second contact 110, refers to an electrical contact, which is understood by those of ordinary skill in the art to refer to a solid material through which electricity can be conducted.

In some embodiments, single-crystalline semiconductor material 108 is between first contact 106 and second contact 110, as shown in FIG. 1A. In some such embodiments, first contact 106 and single-crystalline semiconductor material 108 form first Ohmic contact 114, and second contact 110 and single-crystalline semiconductor material 108 form second Ohmic contact 116. As used herein, the term “Ohmic contact” is given its ordinary meaning in the art and generally refers an electrical junction between a contact and a conducting material that has a linear current-voltage curve. The first contact and/or the second contact may comprise any of a variety of suitable materials (e.g., metals) that used to form an Ohmic contact, which would be known to a person of ordinary skill in the art. In certain embodiments, for example the first contact and/or second contact may comprise gold, silver, copper, and/or aluminum. Other metals are also possible.

The first contact and/or the second contact may have any of a variety of suitable thicknesses. Referring to FIG. 1A, for example, first contract 106 has thickness 112c and second contact 110 has thickness 112d. In certain embodiments, the first contact and/or the second contact has a thickness of less than or equal to 1 micrometer, less than or equal to 500 nm, less than or equal to 200 nm, less than or equal to 100 nm, or less than or equal to 50 nm. In some embodiments, the first contact and/or the second contact has a thickness of greater than or equal to 20 nm, greater than or equal to 50 nm, greater than or equal to 100 nm, greater than or equal to 200 nm, or greater than or equal to 500 nm. Combinations of the above recited ranges are also possible (e.g., the first contact and/or the second contact has a thickness of less than or equal to 1 micrometer and greater than or equal to 20 nm, the first contract and/or the second contact has thickness less than or equal to 500 nm and greater than or equal to 200 nm). Other ranges are possible.

The first contact and/or the second contact may have any of a variety of suitable lengths and/or widths. Referring to FIG. 1B, for example, second contact 110 has length 124b and width 126b, in accordance with some embodiments. In some embodiments, the first contact and/or the second contact has a length and/or width of greater than or equal to 500 nm, greater than or equal to 1 micrometer, greater than or equal to 10 micrometers, greater than or equal to 100 micrometers, greater than or equal to 300 micrometers, greater than or equal to 500 micrometers, greater than or equal to 1 mm, or greater. In certain embodiments, the first contact and/or the second contact has a length and/or width of less than or equal to 10 mm, less than or equal to 1 mm, less than or equal to 500 micrometers, less than or equal to 300 micrometers, less than or equal to 100 micrometers, less than or equal to 10 micrometers, less than or equal to 1 micrometer, or less. Combinations of the above recited ranges are possible (e.g., the first contact and/or the second contact has a length and/or width of greater than or equal to 500 nm and less than or equal to 10 mm, or greater than or equal to 300 micrometers and less than or equal to 1 mm). Other ranges are also possible.

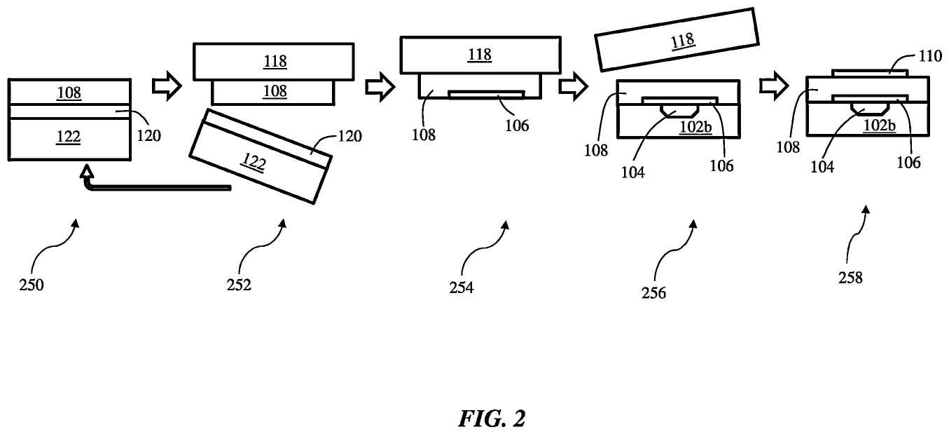

In some embodiments, a method of forming a device is described. FIG. 2 shows, according to certain embodiments, a method of forming a device.

In certain embodiments, the method comprises forming the single-crystalline semiconductor material over a two-dimensional (2D) material (e.g., graphene) positioned over a source (e.g., growth) substrate (e.g., an AlN wafer). See, for example, step 250 in FIG. 2, in which single-crystalline semiconductor material 108 is formed on 2D material 120 positioned over growth substrate 122. In some embodiments, the single-crystalline semiconductor material is grown (e.g., epitaxially grown) on the 2D material. In certain embodiments, the epitaxial growth of the single-crystalline semiconductor material on the 2D material may be performed by chemical vapor deposition (e.g., metal organic chemical vapor deposition), molecular beam epitaxy, and/or pulsed laser deposition.

The fabrication of semiconductor materials on 2D materials is further described in International Patent Application No. PCT/US2016/050701, filed Sep. 8, 2016, published as International Patent Application No. WO 2017/044577 on Mar. 16, 2017, and entitled “SYSTEMS AND METHODS FOR GRAPHENE BASED LAYER TRANSFER,” which is incorporated herein by reference in its entirety for all purposes.

The growth substrate may comprise any of a variety of suitable materials. In some embodiments, for example, the growth substrate comprises silicon, sapphire (e.g., aluminum oxide), STO, zinc oxide, magnesium aluminate, gadolinium gallium garnet, yttrium iron garnet, gadolinium scandate, lanthanum aluminate, barium titanate, lithium niobate, lithium tantalate, lead magnesium niobate-lead titanate, silicon carbide (SiC), a III-nitride material (e.g., AlN, GaN), and the like.

In some embodiments, the 2D material consists of a single monolayer of 2D material (e.g., a single monolayer of graphene). In other embodiments, multiple layers of 2D materials (e.g., multiple layers of graphene) can be used.

While FIG. 2 shows the use of graphene (e.g., monolayer graphene or multilayer graphene) as a 2D material, other types of 2D materials could also be used. In some embodiments, the 2D material comprises one or more transition metal dichalcogenide (TMD) monolayers, which are atomically thin materials of the type MX₂, with M being a transition metal atom (e.g., Mo, W, etc.) and X being a chalcogen atom (e.g., S, Se, or Te). In a TMD lattice, one layer of M atoms is usually sandwiched between two layers of X atoms. In another embodiment, the 2D material comprises boron nitride (e.g., hexagonal boron nitride). In yet another example, the 2D material can include a single-atom layer of metal, such as palladium and rhodium. Out of these 2D materials, graphene can have several desirable properties. For example, graphene is a crystalline film and is a suitable substrate for growing epitaxial over-layers. Second, graphene's weak interaction with other materials can substantially relax the lattice mismatching rule for epitaxial growth, potentially permitting the growth of most semiconducting films with low defect densities. Third, epilayers grown on a graphene substrate can be easily and precisely released from the substrate owing to graphene's weak van der Waals interactions, thereby allowing rapid mechanical release of epilayers without post-release reconditioning of the released surface. Fourth, graphene's mechanical robustness can increase or maximize its reusability for multiple growth/release cycles.

In certain embodiments, the 2D material can be used as a release layer. Accordingly, in certain embodiments, the method comprises removing (e.g., exfoliating) the single-crystalline semiconductor material from the 2D material positioned over the source (e.g., growth) substrate. In some embodiments, the single-crystalline semiconductor material may be removed from the 2D material positioned over the source (e.g., growth) substrate using a first substrate (e.g., a transfer substrate, such as a stressor and/or handler). Referring to step 252 in FIG. 2, for example, single-crystalline semiconductor material 108 is removed from 2D material 120 positioned over growth substrate 122 using first substrate 118.

The first substrate (e.g., transfer substrate) may be a metal stressor, in some embodiments. In some such embodiments, the first substrate (e.g., transfer substrate) may be used to peel the single-crystalline semiconductor material from the 2D material positioned over the source (e.g., growth) substrate under an internal stress of greater than or equal to 100 MPa and less than or equal to 1 GPa.

In certain embodiments, after removal of single-crystalline semiconductor material 108, 2D material 120 and growth substrate 122 may be recycled and reused to grow (e.g., epitaxially grow) a subsequent single-crystalline semiconductor material, thereby reducing overall fabrication and processing costs.

In certain embodiments, the method comprises forming a first contact over the single-crystalline semiconductor material. In certain embodiments, the first contact is formed over a side of the single-crystalline semiconductor material that is opposite a side of the single-crystalline semiconductor material that is facing the first substrate (e.g., transfer substrate). Referring to step 254 in FIG. 2, for example, first contact 106 is formed over the side of single-crystalline semiconductor material 108 that is opposite the side of single-crystalline semiconductor material 108 that is facing first substrate 118. According to certain embodiments, forming the first contact over the single-crystalline semiconductor material comprises depositing the first contact material on the single-crystalline semiconductor material. In some embodiments, the first contact and the single-crystalline semiconductor material may be in direct contact. In some other embodiments, one or more intermediate layers may be disposed between the first contact and the single-crystalline semiconductor material.

The method may comprise, in certain embodiments, transferring the single-crystalline semiconductor material and the first contact from a first substrate to a second substrate (e.g., a receiving substrate, such as a preconfigured performance substrate). Referring to step 256 in FIG. 2, for example, single-crystalline semiconductor material 108 and first contact 106 may be transferred from first substrate 118 to second substrate 102b. Second substrate 102b may, in certain embodiments, comprise cavity 104, and at least a portion of single-crystalline semiconductor material 108 is positioned over cavity 104 of second substrate 102b after the transfer.

In certain embodiments, after transferring the single-crystalline semiconductor material and the first contact from the first substrate (e.g., transfer substrate) to the second substrate (e.g., receiving substrate), for example, step 256 in FIG. 1A, the device may be configured such that the first contact is between the second substrate (e.g., receiving substrate) and the single-crystalline semiconductor material. Referring to step 256 of FIG. 2, for example, first contact 106 is between second substrate 102b and single-crystalline semiconductor material 108. As explained above in reference to FIG. 1A, in some embodiments first contact 106 and single-crystalline semiconductor material 108 form a first Ohmic contact.

According to some embodiments, the method comprises forming a second contact over the single-crystalline semiconductor material. In certain embodiments, the second contact is formed over a side of the single-crystalline semiconductor material that is opposite a side of the single-crystalline semiconductor material that is facing the second substrate (e.g., receiving substrate). Referring to step 258 in FIG. 2, for example, second contact 110 is formed over a side of the single-crystalline semiconductor material 108 that is opposite the side of the single-crystalline semiconductor material 108 that is facing second substrate 102b. According to certain embodiments, forming the second contact over the single-crystalline semiconductor material comprises depositing the second contact material on the single-crystalline semiconductor material. In some embodiments, the second contact and the single-crystalline semiconductor material may be in direct contact. In some other embodiments, one or more intermediate layers may be disposed between the second contact and the single-crystalline semiconductor material.

In certain embodiments, after forming the second contact on the single-crystalline semiconductor material (e.g., step 258 in FIG. 2), the device may be configured such that the single-crystalline semiconductor material is between the first contact and the second contact. Referring to step 258 of FIG. 2, for example, single-crystalline semiconductor material 108 is between first contact 106 and second contact 110. As explained above in reference to FIG. 1A, in certain embodiments second contact 110 and single-crystalline semiconductor material 108 form a second Ohmic contact.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an.” as used herein in the specification and in the claims, unless clearly indicated to the contrary, should be understood to mean “at least one.”

The phrase “and/or.” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B.” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A device, comprising:
a substrate comprising a cavity;
a single-crystalline semiconductor material positioned at least partially over the cavity of the substrate;
a first contact; and
a second contact;
wherein:
the first contact is between the substrate and the single-crystalline semiconductor material;
the first contact and the single-crystalline semiconductor material form a first Ohmic contact;
the single-crystalline semiconductor material is between the first contact and the second contact; and
the second contact and the single-crystalline semiconductor material form a second Ohmic contact.

2. The device of claim 1, wherein the device is a resonator.

3. The device of claim 2, wherein the resonator is a bulk acoustic resonator.

4. The device of claim 1, wherein the single-crystalline semiconductor material is a piezoelectric material.

5. The device of claim 1, wherein the single-crystalline semiconductor material is a III-nitride material.

6. The device of claim 1, wherein the single-crystalline semiconductor material is a metal oxide.

7. The device of claim 1, wherein the thickness of the single-crystalline semiconductor material is less than or equal to 10 micrometers.

8. The device of claim 1, wherein the thickness of the single-crystalline semiconductor material is less than or equal to 1 micrometer.

9. The device of claim 1, wherein the thickness of the single-crystalline semiconductor material is less than or equal to 100 nm.

10. A method of forming a device, comprising:
transferring a single-crystalline semiconductor material and a first contact from a first substrate to a second substrate such that at least a portion of the single-crystalline semiconductor material is positioned over a cavity of the second substrate; and
forming a second contact over a side of the single-crystalline semiconductor material that is opposite a side of the single-crystalline semiconductor material that is facing the second substrate;
wherein, after the transferring and the forming:
the first contact is between the second substrate and the single-crystalline semiconductor material;
the first contact and the single-crystalline semiconductor material form a first Ohmic contact;
the single-crystalline semiconductor material is between the first contact and the second contact; and
the second contact and the single-crystalline semiconductor material form a second Ohmic contact.

11. The method of claim 10, wherein the device is a resonator.

12. The method of claim 11, wherein the resonator is a bulk acoustic resonator.

13. The method of claim 10, wherein the single-crystalline semiconductor material is a piezoelectric material.

14. The method of claim 10, wherein the single-crystalline semiconductor material is a III-nitride material.

15. The method of claim 10, wherein the single-crystalline semiconductor material is a metal oxide.

16. The method of claim 10, wherein the thickness of the single-crystalline semiconductor material is less than or equal to 10 micrometers.

17. The method of claim 10, wherein the thickness of the single-crystalline semiconductor material is less than or equal to 1 micrometer.

18. The method of claim 10, wherein the thickness of the single-crystalline semiconductor material is less than or equal to 100 nm.

19. The method of claim 10, further comprising forming the first contact over the single-crystalline semiconductor material and subsequently transferring the single-crystalline semiconductor material and the first contact from the first substrate to the second substrate.

20. The method of claim 10, further comprising removing the single-crystalline semiconductor material from a two-dimensional material positioned over a source substrate, subsequently forming the first contact over the single-crystalline material, and subsequently transferring the single-crystalline semiconductor material and the first contact to the second substrate.

21. The method of claim 10, further comprising forming the single-crystalline semiconductor material over a two-dimensional material positioned over a source substrate, subsequently removing the single-crystalline semiconductor material from the two-dimensional material positioned over the source substrate, subsequently forming the first contact over the single-crystalline material, and subsequently transferring the single-crystalline semiconductor material and the first contact to the second substrate.

22. The method of claim 10, wherein the two-dimensional material comprises graphene, a transition metal dichalcogenide, and/or boron nitride.
